(19) United States
(12) Patent Application Publication
(10) Pub. No.: US 2017/0004863 A1
(43) Pub. Date: Jan. 5, 2017

(54) MEASURING DEVICE WITH MAGNETICALLY COUPLED DATA TRANSMITTING AND DATA READING PARTS

(71) Applicant: PRÜEFTECHNIK DIETER BUSCH AG, Ismaning (DE)

(72) Inventor: Heinrich LYSEN, Garching (DE)

(21) Appl. No.: 15/115,367

(22) PCT Filed: Jan. 15, 2015
(86) PCT No.: PCT/DE2015/200003

§ 371 Date: Jul. 29, 2016

(30) Foreign Application Priority Data
Jan. 30, 2014 (DE) 10 2014 201 666.5

(51) Int. Cl. G11C 7/00; G01D 15/00

(52) U.S. Cl. CPC G11C 7/00; G01D 15/00

(57) ABSTRACT

A measuring device and system including at least one transmitting part which can be attached to measurement objects and which has at least one data memory and at least two first electrical contacts having respective surfaces that form respective sub-areas of a bearing face of the transmitting part, at least one data reading part which has at least two second electrical contacts having respective surfaces that form respective sub-areas of a bearing face of the data reading part, and at least one magnet. The measuring device is designed to assume an uncoupled state in which the first electrical contacts are at a distance from the second electrical contacts, and to assume a coupled state in which the data reading part and the transmitting part are coupled to one another due to an attraction force brought about by the magnet.

The present invention relates to a measuring device with a transmitting part and a data reading part as well as to a system with such a measuring device.

Systems which comprise a measuring device with a transmitting part which can be attached to an object to be measured and a data reading part are known, for example, from EP 0 211 212 B1 and WO 99/05486 A1, while WO 91/16636 A1 presents an acceleration sensor which is arranged on a carrier. The transmitting part is frequently provided with a data memory. Measured variables of the object to be measured which are acquired by various sensors, for example temperature sensors, such as, for example, the temperature of said object to be measured, can be buffered in the data memory. In addition, an identifier, by means of which a measuring point on the object to be measured, to which the transmitting part is attached, can be uniquely identified, is often stored in the data memory. The data reading part can be used to read all of this data from the data memory for further processing. For this purpose, the data reading part is coupled to the transmitting part. In particular, when the measuring device serves for vibration measurement or oscillation measurement, the data reading part is also equipped with a corresponding sensor which permits the data reading part to measure vibrations or oscillations of the object to be measured, which have been transmitted mechanically to the data reading part from the transmitting part, directly and in real time, instead of reading from the data memory data which has been previously measured by other sensors and stored in the data memory. It is problematic with such devices that not only is the data reading part mechanically securely and fixedly coupled to the transmitting part, but also moreover reliable formation of contact between the electrical contacts of the transmitting part and the data reading part has to be ensured so that data can be read from the data memory without errors. All this requires coupling mechanisms which are extremely complex and therefore difficult to manufacture, and which also involve high costs. In addition, the coupling of the data reading part to the transmitting part also proves time-consuming and awkward.

The object of the present invention is therefore to provide a measuring device with a transmitting part and a data reading part, a system with such a measuring device and a transmitting part which is suitable for this purpose and a data reading part, which have or give rise to a simple and robust coupling mechanism between the transmitting part and the data reading part.

This object is achieved by means of the measuring device having the features of claim 1, by means of the system having the features of claim 9, by means of the transmitting part having the features of claim 10 and by means of the data reading part having the features of claim 11. Preferred exemplary embodiments are the subject matter of the dependent claims.

According to the present invention, the first electrical contacts or contact segments of the transmitting part have surfaces which form respective sub-areas of a bearing face or attachment face of the transmitting part. Likewise, the second electrical contacts or contact segments of the data reading part have surfaces which form respective sub-areas of a bearing face or attachment face of the data reading part. In the uncoupled state, in which the bearing face of the transmitting part is spaced apart or separated from the bearing face of the data reading part, and in which the first electrical contacts are spaced apart or separated from the second electrical contacts, in particular the data reading part and the transmitting part are also spaced apart or separated from one another as such. In contrast, the data reading part and the transmitting part are, in the coupled state of the measuring device, coupled to one another owing to the attractive force which is brought about by the magnet, wherein at least the bearing face of the transmitting part and the bearing face of the data reading part as well as the first and second electrical contacts bear one against the other. As a result, a coupling mechanism which is simple and cost-effective to manufacture is implemented, said coupling mechanism also permitting fast and convenient coupling and uncoupling of the data reading part to and from the transmitting part. In addition, mechanically stable coupling of the data reading part to the transmitting part is possible as a result of the magnetic attractive force, while the specific embodiment of the bearing faces and of the electrical contacts gives rise to a connection between the transmitting part and the data reading part which conducts electrically without faults and is electrically insulated from the outside, as a result of which data can be read out from the data memory without errors.

In particular, the surfaces of the first electrical contacts form sub-areas, disjunctive or separated from one another, of the bearing face of the transmitting part, which can either be completely or merely partially formed by the entirety of the surfaces of the first contacts, wherein the bearing face of the transmitting part can be an incoherent face as well as a coherent face. Correspondingly, the surfaces of the second electrical contacts form sub-areas, disjunctive or separated from one another, of the bearing face of the data reading part which can be formed either completely or merely partially by the entirety of the surfaces of the second contact, wherein the bearing face of the data reading part can be an incoherent face as well as a coherent face. Incoherent bearing faces are present, in particular, in the case of protruding contacts, wherein a bearing face can preferably be completely formed by the entirety of those surfaces of contacts which form sub-areas of this bearing face. In this context, in the coupled state of the measuring device the bearing face of the transmitting part and the bearing face of the data reading part bear one against the other at least with the sub-areas formed by the surfaces of the electrical contacts, regardless of whether said bearing faces are incoherent or coherent faces. In the coupled state of the measuring device, the attractive force which is brought about by the magnet is preferably normal or essentially normal with respect to the surfaces of the first electrical contacts and the surfaces of the second electrical contacts or the bearing face of the transmitting part and the bearing face of the data reading part, but they can also form an angle with these surfaces.

The object to be measured can be any desired apparatus, machine or system as well as fixed or movable parts thereof, such as, for example, shafts, axles or rollers. The transmitting part can be fixedly or movably or releasably attached to the object to be measured.

The transmitting part or the data reading part are preferably manufactured at least partially from a steel such as, for example, a machining steel, which can also be coated with a galvanic protective layer. Quite generally, the first and second contacts can be manufactured from any desired metal such as, for example, copper, nickel, stainless steel or gold. For example, gold contacts are advantageous owing to their electrical properties and the resistance to corrosion.

The measuring device can quite generally be provided for measuring any desired measured variables of the object to be measured, for which purpose it can have one or more identical or different sensors which can be arranged at different locations on the object to be measured, in or on the transmitting part, in or on the data reading part or exclusively in the data reading part. Measured values which are acquired by sensors arranged outside the data reading part can be buffered in the data memory of the transmitting part, from which data memory they can be read by the data reading part after the coupling of the data reading part to the transmitting part or after the changing of the measuring device into the coupled state. In addition, in order to uniquely identify the transmitting part or the measuring location at which the transmitting part is attached to the object to be measured, an identifier can be stored in the data memory.

In contrast, in order to measure certain measured variables such as, for example, to measure oscillations or vibrations of the object to be measured, sensors can be provided in or on the data reading part itself or as a part thereof. In such cases, in the coupled state of the measuring device oscillations or vibrations are transmitted mechanically by the transmitting part to the data reading part as measured variables of the object to be measured, from which data reading part they can be acquired by the sensor which is arranged there. In the data memory of the transmitting part, merely an identifier can then be stored instead of data for previously measured measured variables, which identifier can be read by the data reading part in the coupled state of the measuring device, in order to be able to uniquely assign the measurement or the acquired measured values to a measuring point on the object to be measured. In particular, the measuring device can have one or more sensors which are arranged exclusively in the data reading part.

Consequently, in the case of the measuring device, the data reading part and/or the transmitting part can quite generally have at least one sensor and/or the measuring device can have at least one sensor which can be attached to the object to be measured and has the purpose of acquiring at least one measured variable, which sensor is a temperature sensor or an oscillation sensor or a monoaxial oscillation sensor or a triaxial oscillation sensor or an acceleration sensor or a high-frequency acceleration sensor or a micromechanical acceleration sensor or a piezo-electric acceleration sensor. In this context, temperature sensors are preferably provided, as part of the transmitting part for measuring the temperature of the object to be measured, in the surroundings of the transmitting part. The measured temperature values are preferably stored in the data memory of the transmitting part. If the measuring device is provided for measuring oscillations or vibrations of the object to be measured, it preferably has an oscillation sensor or acceleration sensor which is included in the data reading part. This can be a mono-axial vibration sensor which measures oscillations or vibrations in a direction, usually in a normal direction with respect to the surface of the object to be measured, or a triaxial vibration sensor which measures oscillations or vibrations in three directions which are perpendicular to one another, wherein one of these directions is usually a normal direction with respect to the surface of the object to be measured. The acceleration sensors can be any desired acceleration sensors such as, for example, known micromechanical or piezo-electric acceleration sensors. Since frequencies which occur in machine systems usually lie in the region of 0 kHz to 40 kHz, the acceleration sensor is particularly preferably a high-frequency acceleration sensor for acquiring oscillations in the high-frequency range from 100 Hz to 20 kHz or from 100 Hz to 30 kHz or from 100 Hz to 40 kHz or from 1 kHz to 30 kHz or from 1 kHz to 40 kHz or from 30 kHz to 40 kHz. The data reading part particularly preferably has at least one triaxial oscillation sensor and at least one high-frequency acceleration sensor for supporting the latter.

However, the respective bearing faces can quite generally also be bent or curved. In one preferred embodiment of the measuring device according to the invention, the respective surfaces of the first electrical contacts are flat and parallel and aligned with respect to one another and the respective surfaces of the second electrical contacts are also flat and parallel and aligned with respect to one another. In such a measuring device, the bearing face of the transmitting part and the bearing face of the data reading part are preferably also flat. In addition, after the attachment of the transmitting part of a measuring device which is embodied in such a way to a flat face of the object to be measured in the coupled state of the measuring device, the surfaces of the first and second contacts and therefore also the bearing face of the transmitting part and the bearing face of the data reading part are preferably oriented in parallel with respect to this face. If the transmitting part is attached to a curved face of the object to be measured, in the coupled state of such a measuring device flat surfaces of the first and second contacts or the flat bearing face of the transmitting part and the flat bearing face of the data reading part are preferably oriented parallel with respect to a tangential plane of the curved face of the object to be measured. In particular, the attractive force, brought about by the magnet, in the coupled state of a measuring device with flat bearing faces is preferably located perpendicularly with respect to the surfaces of flat first and second contacts, that is to say in the coupled state of the measuring device the attractive force brought about by the magnet is preferably a normal force with respect to the surfaces of the first and second contacts. As a result, the coupling of the data reading part to the transmitting part is particularly simplified.

A number of embodiments of the measuring device according to the invention have more than two first and more than two second contacts. For example, the measuring device can have three first electrical contacts with respective surfaces and three second electrical contacts with respective surfaces, wherein the surfaces of the first electrical contacts are arranged with their area centroids at corners of a first triangle, and the surfaces of the second electrical contacts are arranged with their area centroids at corners of a second triangle. In this case, in each case a contact of the first and second contacts can be provided for connecting to a negative pole of a power source, which power source can be located, for example, within the transmitting part or the data reading part or outside these two parts, and in each case a contact of the first and second contacts can be provided for connecting to a positive pole of the power source, and in each case a contact of the first and second contacts can be provided for transmitting signals. In the coupled state of the measuring device, the first and second triangles are preferably congruent with one another.

One embodiment is the measuring device in which the first and second triangles are right-angled or equilateral triangles is particularly preferred, wherein after the transmitting part has been fitted onto a surface of the object to be measured, the sensor which is included in the data reading part is, in the coupled state of the measuring device, at a distance from this surface which is shorter than the diameter or the radius of a circumscribed circle of the first or second triangle or which is shorter than a longest side of the first or second triangle or which is shorter than a shortest side of the first or second triangle. Such an embodiment of the measuring device is advantageous, in particular, when the measuring device is provided for measuring oscillations or vibrations and the sensor which is provided for this purpose is arranged in the data reading part or is part thereof, since the sensor is then at a short distance from the object to be measured. Moments of inertia which are proportional to the square of the distance, in particular of masses of the data reading part which are located on a side of the sensor facing away from the object to be measured, can have a less strong influence in the case of bending and tilting movements and the measurement can therefore be falsified to a lesser degree.

For similar reasons, in the coupled state after the transmitting part has been fitted onto a surface of the object to be measured, a total extent of the measuring device, measured in the normal direction with respect to the surface of the object to be measured, which is shorter than or equal to a total extent of the measuring device, measured parallel with respect to the surface of the object to be measured, is particularly preferred.

The at least one magnet, which brings about the magnetic attractive force in the coupled state of the measuring device, can basically be arranged in or on the data reading part or in or on the transmitting part, or it can be included in the data reading part or in the transmitting part or it can be part of the data reading part or of the transmitting part. This magnet is preferably a permanent magnet but an electromagnet can also equally well be provided. Insofar as only the data reading part or the transmitting part is provided with a magnet, the magnet can act in an attractive fashion on the electrical contacts of the respective other part and bring about the coupling of the data reading part and transmitting part on the basis of the magnetic force acting on the respective contacts. In such an embodiment of the present invention, it is particularly advantageous if the first and second contacts are composed of slightly magnetizable metal. Nevertheless, the transmitting part can as such be mainly fabricated from a slightly magnetizable metal, while the first and second contacts can be, for example, gold contacts. In addition, both the data reading part and the transmitting part can have at least one magnet, since with two attracting magnets larger attractive forces can be achieved in the coupled state of the measuring device, as a result of which the coupling between the data reading part and the transmitting part is mechanically more stable.

The magnet can be shaped in different ways. In the simplest case, the magnet is a rectangular solid. On the other hand, the magnet can also be embodied in the shape of a ring. In this context, the contacts can be arranged with their area centroids distributed along the annular magnet. In other embodiments, the flat surfaces of the contacts are circular and are surrounded or enclosed by a respective annular magnet. However, a shape and arrangement of the magnets in which both the data reading part and the transmitting part have at least one magnet whose magnetic fields or magnetic forces which are brought about thereby center and/or align the data reading part relative to the transmitting part during the changing of the measuring device from the uncoupled state into the coupled state are particularly advantageous. Such an embodiment permits considerably facilitated and accelerated coupling of the data reading part to the transmitting part.

In addition, in the case of the measuring device, a mechanical damper is advantageously provided on a side of the affected first contact or second contact facing away from the respective surface of at least one of the first contacts or second contacts. This damper may be, for example, a plastic layer. By means of such a damper, undesired resonance effects, which occur in the case of vibrations of the object to be measured and are transmitted mechanically from the transmitting part to the data reading part and can bring about adverse effects on measurements or even damage the measuring device, can be suppressed or even entirely avoided.

The measuring device according to the invention can be part of a system which also has at least one operator control part which is or can be connected to the data reading part. The operator control part can be connected to the data reading part, for example, by means of a cable or in a wireless fashion, in particular via a wireless communication link, with the result that the data which is read by the data memory can be transmitted via the cable or in a wireless fashion to the operator control part for further processing or evaluation. In addition, measured values acquired by sensors of the data reading part can be received by the operator control part, via the cable or in a wireless fashion, for further processing or evaluation, if appropriate after buffering. In this context, the operator control part can, in particular, have a graphic display on which the data and/or measured values which are received can be displayed. In particular, the operator control part can be configured for manual or automatic or partially automatic control of the data reading part.

The invention will be explained in more detail below on the basis of preferred exemplary embodiments, in which:

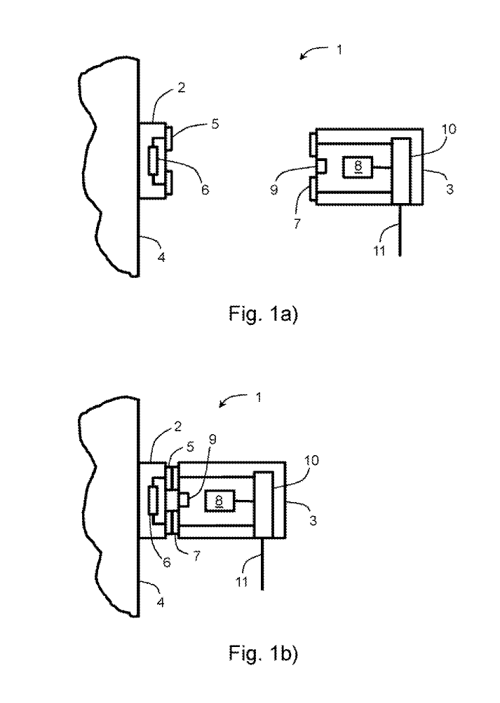

FIG. 1a) shows a cross section through a basic embodiment of a measuring device in the uncoupled state;

FIG. 1b) shows the measuring device from FIG. 1a) in the coupled state;

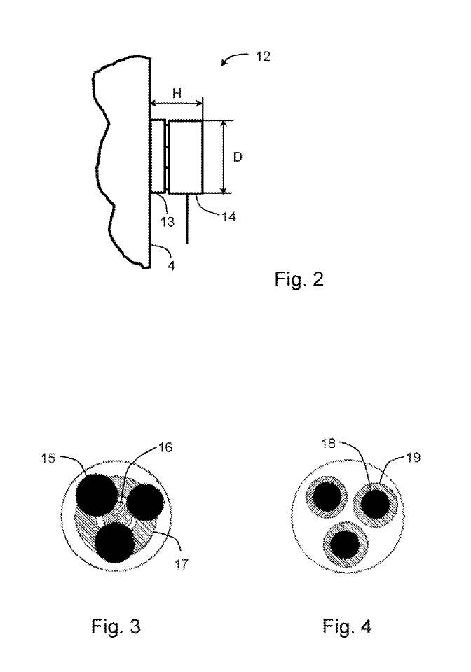

FIG. 2 shows a further embodiment of a measuring device in the coupled state;

FIG. 3 shows a plan view of a configuration with three electrical contacts;

FIG. 4 shows a plan view of a further configuration with three electrical contacts;

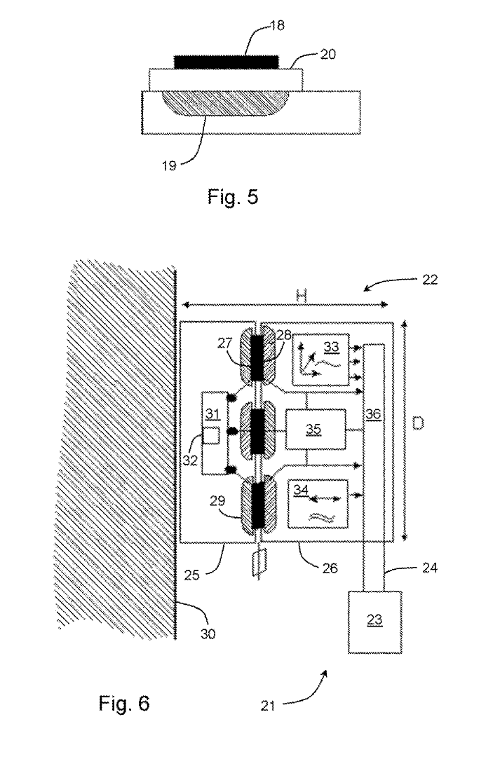

FIG. 5 shows a cross section through part of the configuration in FIG. 4; and

FIG. 6 shows a cross section through a system with a measuring device in the coupled state.

A cross section which is not to scale because it is schematic, through a basic embodiment of a measuring device (1) which is provided for measuring vibrations of machines, is shown in an uncoupled state in FIG. 1a) and in a coupled state in FIG. 1b). The measuring device (1) comprises a transmitting part (2) and a data reading part (3).

The transmitting part (2) which is fabricated from a machining steel can be seen in FIGS. 1a) and 1b) arranged on the surface of a machine (4) which serves as an object to be measured for the measuring device (1). On a surface of the transmitting part (2) facing away from the machine (4), two protruding electrical contacts (5) made of metal are provided, each of which contacts (5) has a flat surface on a side facing away from the machine (4). In this case, the flat surfaces of the contacts (5) are not parallel to one another but instead are also arranged aligned with one another in a plane, with the entirety of the flat surfaces of the contacts (5) forming respective sub-areas of an incoherent bearing face which are disjunctive or separate from one another. In the interior of the transmitting part (2), a data memory (6) which is connected to the contacts (5) is provided. An identifier is stored in the data memory (6).

The data reading part (3) has, on an end side, two electrical contacts (7), each with flat surfaces which are parallel and aligned with respect to one another and which are embodied similarly to the electrical contacts (5) of the transmitting part (2). In particular, the entirety of the flat surfaces of the contacts (7) of the data reading part (3) forms respective separate or disjunctive sub-areas of an incoherent bearing face which is essentially congruent with the bearing face, formed by the entirety of the flat surfaces of the contacts (5) of the transmitting part (2). In addition, a triaxial acceleration sensor (8) is provided in the interior of the data reading part (3). Between the contacts (7), the data reading part (3) has a magnetic pole or magnet (9) whose magnetic forces act in an attracting fashion on the transmitting part (2) which is fabricated from machining steel. Both the contacts (7) and the acceleration sensor (8) are connected to a data bus (10) which leads into an external cable (11).

As already mentioned, the measuring device (1) can both assume the uncoupled state (illustrated in FIG. 1a)) in which the transmitting part (2) and the data reading part (3) are separated from one another, and can also be changed into the coupled state (illustrated in FIG. 1b)) by simply fitting the data reading part (2) onto the transmitting part (3). The coupling or connection of the transmitting part (2) and data reading part (3) is brought about and maintained on the basis of the magnetic attractive force, acting on the transmitting part (2), of the magnet (9). In the coupled state, the transmitting part (2) and the data reading part (3) bear one against the other with their respective contacts or the bearing faces formed by their surfaces, wherein in each case one of the contacts (5) of the transmitting part (2) bears with its flat surface against the flat surface of the respective one of the contacts (7) of the data reading part (3).

In the coupled state of FIG. 1b), the measuring device (1) is operationally ready for measuring vibrations of the machine (4). Here, owing to the electrical connection produced by means of the electrical contacts (5) and (7) which bear one against the other, the identifier which is stored in the data memory (6) of the transmitting part (2) can be read by the data reading part (3) and transmitted to the data bus (10) and from there on via the cable (11) to a device (not illustrated in FIGS. 1a) and 1b)), for example an operator control part or a computer, and the transmitting part (2) or the measuring location on the machine (4) can therefore be identified. The actual measurement of the vibrations of the machine (4) is carried out in the coupled state of the measuring device (1) by means of the acceleration sensor (8), the measured values of which are also transmitted via the data bus (10) and the cable (11) to the external device (not shown) where they can be further processed, analyzed or displayed graphically. In combination with the identifier from the data memory (6), these measured values can be uniquely assigned to the transmitting part (2) or a measurement location on the object to be measured (4). After measurement has taken place, the data reading part (3) can easily be disconnected manually from the transmitting part (2), as a result of which the measuring device (1) is changed from the coupled state in FIG. 1b) back into the uncoupled state in FIG. 1a).

Although in the case of the measuring device (1) the magnet (9) is provided on the data reading part (3), it can alternatively also be arranged on the transmitting part (2) insofar as the data reading part (3) is at least partially composed of a metal which is attracted by the magnetic forces of the magnet (9). Furthermore, both the data reading part (3) and the transmitting part (2) are provided with respective magnets which are arranged with their poles in such a way that in the coupled state of the measuring device (1) they attract one another.

In addition, the surfaces of the electrical contacts (5) of the transmitting part (2) and of the electrical contacts (7) of the data reading part (3) do not necessarily have to be made flat. They can instead also have a curved or bent shape, with the result that the respective bearing faces of the transmitting part (2) and of the data reading part (3) are at least partially in a correspondingly curved or bent shape.

In FIG. 2, instead of the measuring device (1), an alternative measuring device (12) for measuring vibrations of the machine (4) is illustrated in the coupled state, said measuring device (12) having a transmitting part (13) which is attached to the surface of the machine (4), and a data reading part (14) and which corresponds, with the exception of the dimensions, to the measuring device (1) in FIGS. 1a) and 1b). The dimensions of the measuring device (12) are, however, now selected such that in the illustrated coupled state an extent H of the measuring device (12), measured in the normal direction with respect to the surfaces of the contacts of the transmitting part (13) and of the data reading part (14) or in the normal direction with respect to the surface of the machine (4), is smaller than an extent D of the measuring device (12) measured parallel with respect to the surfaces of the contacts or the surface of the machine (4). This dimensioning of the measuring device (12) ensures that the acceleration sensor which is located in the data reading part (14) is located as close as possible to the surface of the machine (4), with the result that inertia effects of masses of the data reading part (14) which are located on a side of the acceleration sensor facing away from the machine (4) have as far as possible no effects on the measurement of the acceleration sensor. Furthermore, with such a flat embodiment of the measuring device (12), the mechanical stability thereof in the coupled state is increased.

Instead of in each case only providing two electrical contacts, in each case three electrical contacts can also be provided for the transmitting part and the data reading part. Various configurations with, in each case, three electrical contacts (15) and (18) which are possible for a transmitting part and for a data reading part are illustrated in FIGS. 3 and 4. Here, for example, in each case one of the three contacts (15) and (18) can be provided for the connection to a positive pole of a power source and in each case one of the contacts (15) and (18) can be provided for the connection to the negative pole of the power source, while the remaining third contact (15) and (18) can be provided for the transmission of data signals.

In the case of the configuration illustrated in FIG. 3, the three electrical contacts (15) which are in the form of full circles with the same diameter are arranged at the corners of a virtual equilateral triangle. A first magnetic pole or magnet (16) in the form of a full circle with a magnetic pole in the form of a full circle and a second magnetic pole or magnet (17) in the form of a circular ring with a magnetic pole in the form of a circular ring is therefore arranged in FIG. 3 underneath the contacts (15), on a side opposite the flat surface of these contacts (15), wherein the first magnet (16) is surrounded by the second magnet (17). The center points of the first magnet (16) and those of the second magnet (17) coincide with the intersection point of the angle bisectors of the virtual triangle, wherein the center points of the contacts (15) are arranged along the center line of the second magnet (17).

In the plan view of a further configuration of three electrical contacts which are in the form of a full circle with the same diameter, which is illustrated in FIG. 4, the electrical contacts (18) are arranged at the corners of a virtual equilateral triangle. However, in contrast to the configuration in FIG. 3, in the configuration in FIG. 4 a respective magnetic pole or magnet (19) which is in the form of a full circle and has a magnetic pole in the form of a full circle is now provided for each individual one of the contacts (18), on a side opposite the flat surfaces of the contacts (18), and therefore underneath the contacts (18) in FIG. 4, wherein the magnets (19) have a larger diameter than the contacts (18), and each magnet (19) is concentric with a respective one of the contacts (18).

A mechanical damper can be provided between the electrical contacts (15) and (18) and the magnets (16), (17) and (19). This is clarified in FIG. 5 which shows, for an embodiment with a mechanical damper, for example a cross section through part of the configuration shown in FIG. 4 in the surroundings of one of the contacts (18). FIG. 5 clearly shows a printed circuit board (20) which is provided as a mechanical damper and is arranged between contact (18) and magnet (19). This printed circuit board (20) is a soft glass fiber epoxide printed circuit board (20) which may be only 0.3 mm thick and brings about the damping of high resonant frequencies and therefore improves the mechanical contact between the transmitting part and the data reading part. However, the transmission of high frequencies is also possible as long as the mass of the data reading part is not too large. Mechanical dampers such as the printed circuit (20) are preferably also provided in other configurations of electrical contacts such as, for example, in the case of the configuration in FIG. 3, to be precise independently of the number of contacts. It is therefore possible, in particular even in the case of the measuring devices (1) and (12) illustrated in FIGS. 1a), 1b) and 2, to provide such a printed circuit board on the transmitting parts (2) and (13) on a side facing away from the flat surfaces of the contacts (5) of the transmitting parts (2) and (13), and correspondingly a printed circuit board can be provided on the data reading parts (3) and (14) on a side facing away from the flat surfaces of the contacts (7) and data reading parts (3) and (14).

FIG. 6 shows a system (21) with a measuring device (22) according to the invention in the coupled state and an operator control part or portable evaluation device (23), which measuring device (22) and evaluation device (23) are connected to one another via a cable (24). Like the measuring devices (1) and (12) described above, the measuring device (22) of the system (21) also has a transmitting part (25) and a data reading part (26), wherein the measuring device (22) can also assume, in addition to the coupled state shown in FIG. 6, an uncoupled state in which the data reading part (26) and transmitting part (25) are separated from one another.

In contrast to the measuring devices (1) and (12), the transmitting part (25) now comprises, however, three protruding contacts (27) which are composed of gold and each have flat surfaces which are parallel and aligned with respect to one another and which form in their entirety a flat incoherent bearing face. Correspondingly, the data reading part (26) also comprises on its end side three protruding contacts (28) which are composed of gold and have respective flat surfaces which are parallel and aligned with respect to one another and which form in their entirety a flat incoherent bearing face and which, in the coupled state of the measuring device (22) illustrated in FIG. 6, bear against the flat surfaces of the contacts (27) and as a result produce an electrically conductive connection between the transmitting part (25) and data reading part (26). As in the case of the configuration of the example in FIG. 4, in the present transmitting part (25) and the present data reading part (26), a disk-shaped magnetic pole or magnet (29) with a diameter which is larger than the diameter of the associated contact (27) or (28) is respectively arranged on a side facing away from the respective surface of each of the contacts (27) and (28). The magnets (29) are arranged on the transmitting part (25) and data reading part (26) and aligned with their pole arrangements in such a way that, in the coupled state of the measuring device (22) which is shown, magnets (29) which lie opposite one another respectively attract one another and as a result bring about a mechanically fixed coupling of the transmitting part (25) and of the data reading part (26), wherein the attraction forces of the magnets (29) act essentially in a normal direction with respect to the flat surfaces of the contacts (27) and (28).

The transmitting part (25) is a machining steel turned part which is covered with a galvanic protective layer and has a diameter of approximately 20 mm and is bonded onto the surface of a machine (30). Said transmitting part (25) comprises both a programmable and erasable data memory (31) which can be connected to the contacts (27) and a temperature sensor (32) for measuring temperatures of the machine (30), wherein measured values which are acquired by the temperature sensor (32) are stored in the data memory (31). In addition, an identifier is stored in the data memory (31).

In contrast, the data reading part (26) has, in addition to the contacts (28) and the magnets (29), also a triaxial acceleration sensor (33), a high-frequency acceleration sensor (34), a parameter memory (35) and a data bus (36) which leads into the external cable (24). The acceleration sensors (33) and (34) as well as the parameter memory (35) are connected to the data bus (36) via respective serial interfaces. The cable (24) therefore connects the measuring device (22) or the data reading part (26) of the measuring device (22) to the portable evaluation device (23). In this context, the dimensions of the measuring device (22) are selected in such a way that their total width D parallel to the surface of the machine (30) is larger than the total height H perpendicular to the surface of the machine (30). As a result, the data reading part (26) is of very flat design, as a result of which it can also measure in the transverse direction with wobbling and can transmit acceleration amplitudes of around 50 g. In addition, the mass of the data reading part (26) is less than 10 g, with the result that it can follow movements of the machine (30) up to accelerations of 100 g.

In the coupled state of the measuring device (22) illustrated in FIG. 6, the data reading part (26) is enabled through the electrical connection produced as a result of the contacts (27) and (28) bearing against one another, to the transmission part (25) or to the data memory (31), to read measured values of the temperature sensor (32) which are stored in the data memory (31) as well as the identifier from the data memory (31) and to transmit them to the portable evaluation device (23) via the data bus (36) and the cable (24). In addition, in the coupled state of the measuring device (22) which is shown, the system (21) can measure vibrations or oscillations of the machine (30) by means of the acceleration sensors (33) and (34), wherein the triaxial acceleration sensor (33) which is known per se is provided for measuring oscillations in three directions which are orthogonal with respect to one another, while the high-frequency acceleration sensor (34) assists the measurement in a normal direction with respect to the surface of the machine (30), since triaxial acceleration sensors (33) usually have a restricted frequency dynamic range. Different parameters which are predefined and stored in the parameter memory (35) can be used in an assisting fashion for the measurement. Measured values which are acquired by the acceleration sensors (33) and (34) are transferred via the respective serial interfaces to the data bus (36) and transmitted from there via the cable (24) to the portable evaluation device (23). The evaluation device (23) stores and analyzes the received data and permits it to be displayed graphically on a screen (not shown in FIG. 6). In addition, the measurement operation of the measuring device (22) can be controlled by means of the evaluation device (23) by transmitting control commands from the evaluation device (23) via the cable (24) and the data bus (36) to the acceleration sensors (33) and (34) and the parameter memory (35) as well as via the electrical connection of the contacts (27) and (28) which bear one against the other to the data memory (31) and the temperature sensor (32).

### LIST OF REFERENCE NUMERALS

1 Measuring device

2 Transmitting part

3 Data reading part

4 Machine

5 Electrical contact of the transmitting part

6 Data memory

7 Electrical contact of the data reading part

8 Triaxial acceleration sensor

9 Magnet or magnetic pole

10 Data bus

11 Cable

12 Measuring device

13 Transmitting part

14 Data reading part

15 Contact

16 Magnet or magnetic pole

17 Magnet or magnetic pole

18 Contact

19 Magnet or magnetic pole

20 Printed circuit board

21 System

22 Measuring device

23 Evaluation device

24 Cable

25 Transmitting part

26 Data reading part

27 Contacts

28 Contacts

29 Magnet or magnetic pole

30 Machine

31 Data memory

32 Temperature sensor

33 Triaxial acceleration sensor

34 High frequency acceleration sensor

35 Parameter memory

36 Data bus

1. A measuring device comprising:
at least one transmitting part which can be attached to objects to be measured and has at least one data memory and at least two first electrical contacts with respective surfaces which form respective sub-areas of a bearing face of the transmitting part,
at least one data reading part with at least two second electrical contacts with respective surfaces which form respective sub-areas of a bearing face of the data reading part, and
at least one magnet, wherein
the measuring device is configured
to assume an uncoupled state in which the first electrical contacts are spaced apart from the second electrical contacts, and
to assume a coupled state in which the data reading part and the transmitting part are coupled to one another owing to an attractive force which is brought about by the magnet, wherein the bearing face of the transmitting part and the bearing face of the data reading part bear one against the other, and in each case one of the first electrical contacts bears with its surface against the surface of a respective one of the second electrical contacts, as a result of which the electrically conductive connections exist between respective first contacts which bear one against the other and second contacts which permit the data reading part to read data stored in the data memory).

2. The measuring device as claimed in claim 1, wherein the data reading part and/or the transmitting part have/has at least one sensor and/or at least one sensor which can be attached to the object to be measured and has the purpose of acquiring at least one measured variable, which sensor is a temperature sensor or an oscillation sensor or a monoaxial oscillation sensor or a triaxial oscillation sensor or an acceleration sensor or a high-frequency acceleration sensor or a micromechanical acceleration sensor or a piezo-electric acceleration sensor.

3. The measuring device as claimed in claim 1, wherein the respective surfaces of the first electrical contacts are flat and parallel and aligned with respect to one another and in which the respective surfaces of the second electrical contacts are flat and parallel and aligned with respect to one another.

4. The measuring device as claimed in claim 1, which has three first electrical contacts with respective surfaces and three second electrical contacts with respective surfaces, wherein the surfaces of the first electrical contacts are arranged with their area centroids at corners of a first triangle, and the surfaces of the second electrical contacts are arranged with their area centroids at corners of a second triangle.

5. The measuring device as claimed in claim 4, wherein the first and second triangles are right-angled or equilateral triangles, wherein after the transmitting part has been fitted onto a surface of the object to be measured, the sensor which is included in the data reading part is, in the coupled state of the measuring device, at a distance from this surface which is shorter than a diameter or the radius of a circumscribed circle of the first or second triangle or which is shorter than a longest side of the first or second triangle or which is shorter than a shortest side of the first or second triangle.

6. The measuring device as claimed in claim 1, wherein the coupled state after the transmitting part has been fitted onto a surface of the object to be measured, a total extent of the measuring device, measured in the normal direction with respect to the surface of the object to be measured, is shorter than or equal to a total extent of the measuring device, measured parallel with respect to the surface of the object to be measured.

7. The measuring device as claimed in claim 1, wherein both the data reading part and the transmitting part have at least one magnet, the magnetic fields of which center and/or align the data reading part relative to the transmitting part when the measuring device is changed from the uncoupled state into the coupled state.

8. The measuring device as claimed in claim 1, wherein a mechanical damper is provided on a side of the affected first contact or second contact facing away from the respective surface of at least one of the first contacts or second contacts.

9. A system having at least one measuring device as claimed in claim 1, and at least one operator control part which is or can be connected to the data reading part via a cable or in a wireless fashion.

10. A transmitting part for a measuring device as claimed in claim 1, having at least one measuring device and at least one operator control part which is or can be connected to the data reading part via a cable or in a wireless fashion.

11. A data reading part for a measuring device as claimed in claim 1, having at least one measuring device and at least one operator control part which is or can be connected to the data reading part via a cable or in a wireless fashion.

12. A transmitting part for a system as claimed in claim 9, having at least one measuring device and at least one operator control part which is or can be connected to the data reading part via a cable or in a wireless fashion.

13. A data reading part for a system as claimed in claim 9, having at least one measuring device and at least one operator control part which is or can be connected to the data reading part via a cable or in a wireless fashion.
